(19) United States
(12) Patent Application Publication
(10) Pub. No.: US 2022/0173570 A1
(43) Pub. Date: Jun. 2, 2022

(54) STRUCTURE OF IMPEDANCE SIGNAL LINES FOR TO-CAN TYPE SEMICONDUCTOR PACKAGE

(71) Applicant: OPTO ELECTRONICS SOLUTIONS, Gwangju (KR)

(72) Inventors: Moon Soo PARK, Irvine, CA (US); Young Sin KO, Gwangju (KR)

(73) Assignee: OPTO ELECTRONICS SOLUTIONS, Gwangju (KR)

(21) Appl. No.: 17/537,480

(22) Filed: Nov. 29, 2021

(30) Foreign Application Priority Data
Nov. 30, 2020 (KR) 1020200164275

(51) Int. Cl. H01S 5/02212; H01S 5/02345; H01S 5/062

(52) U.S. Cl. CPC H01S 5/02212; H01S 5/06203; H01S 5/02345

(57) ABSTRACT

A structure for impedance signal lines of a transistor outline (TO)-can type semiconductor package is disclosed. The TO-can type semiconductor package may include a header including a semiconductor laser diode disposed on one side thereof; a signal line penetrating the header and including a one end protruding from the one side of the header; and an edge-coupled microstrip (ECM) portion connected to the signal line. The ECM portion is configured to include a dielectric and ECM lines are formed as conductive patterns having predetermined widths and leaving a predetermined space therebetween on a first side of the dielectric, and respectively connected to the signal lines.

### CROSS-REFERENCE TO RELATED APPLICATION(S)

This application claims the benefit of Korea Patent Application No. 10-2020-0164275, filed Nov. 30, 2021, titled “STRUCTURE OF IMPEDANCE SIGNAL LINES FOR TO-CAN TYPE SEMICONDUCTOR PACKAGE,” the entire content of which is incorporated herein in its entirety.

### FIELD OF THE INVENTION

An embodiment relates to a structure for impedance signal lines of a transistor outline (TO)-can type semiconductor package.

### DESCRIPTION OF THE RELATED ART

With recently increased demand and widespread use of optical devices, demand for data transmission using fiber optics has been rapidly increasing in various networks such as a local area network (LAN). In particular, researches related to high-speed data transmission have been actively conducted, and as a result various package-type semiconductor laser diodes have been introduced.

FIGS. 1A to 1C are diagrams showing structures for signal lines of a conventional TO-can type module package, and FIGS. 2A and 2B are diagrams showing results of simulating RF characteristics of a conventional signal line structure.

Referring to FIGS. 1A to 1C, the structure includes a header 10 having specific impedance, and a signal line 20 penetrating or passing through a feedthrough. The penetrating signal line 20 includes a single line or two lines, which are not connected to each other, for processing differential signals. As necessary, multiple signal lines that are not connected to one another may penetrate or pass through the header 10 together. In this case, a penetrated portion is filled with a dielectric 11 generally made of a glass material so that the penetrating signal lines do not connect to each other but stay isolated from the header portion. By adjusting the dielectric permittivity of the glass material, the size of a feedthrough hole, the thickness of the penetrating signal line 20, and the distance between two or more penetrating signal lines 20, it is possible to design desired characteristic impedance. To make it easier to mount a semiconductor laser or the like parts onto the header, the signal line 20 has been used as it is lengthened as shown in FIG. 1B.

As shown in FIG. 1C, when a semiconductor part 40 is mounted onto a TO-can, a semiconductor laser diode 43 or the like device is attached or disposed on a ceramic plate 42 and this ceramic plate 42 is then mounted on the header 10. Further, when it is necessary to control the temperature of the semiconductor laser diode 43 through a thermoelectric cooler (TEC) 41, the TEC 41 is attached to the header 10 and then the ceramic plate 42 is attached thereon. In this case, as shown in FIGS. 1B and 1C, the signal line 20 penetrating the header 10 is lengthened above the header 10 and connected to the parts such as the signal line or the laser diode of the ceramic plate by a bonding wire.

With this structure, the signal line portion and the header portion are different in impedance. As shown in FIGS. 1B and 1C, the signal line 20 is exposed to air and there are no other materials around the signal line 20. Therefore, the signal line 20 usually serves as an inductor and increases inductance as a frequency becomes higher, thereby causing a problem that a signal from the header portion is not transmitted well to the semiconductor laser or other parts on the ceramic plate.

FIGS. 2A and 2B show S parameters of a header with an additional signal line and a header with no additional signal lines. Here, S11 of the header with no additional signal lines shows a characteristic of −20 dB or below even at 30 GHz, but S11 of the header with the additional signal line (with leads), i.e., the header with the signal line lengthened by 1 mm shows a rapidly deteriorating characteristic.

Further, S21 of the header with no additional signal lines shows almost flat characteristics at 30 GHz or higher, but S21 of the header with the additional signal line (with leads) shows a characteristic that a bandwidth of −3 dB is limited to about 25 GHz.

FIGS. 3A and 3B are diagrams showing another structure of a signal line of a conventional TO-can type module package, and FIGS. 4A and 4B are diagrams showing results of simulating RF characteristics of another signal line structure shown in FIGS. 3A and 3B.

Referring to FIGS. 3A and 3B, a dielectric 30 is interposed between two differential signal lines 20a and 20b in order to solve the problems of the structures shown in FIGS. 1A to 1C.

A dielectric 30 is interposed between the two differential signal lines 20a and 20b, and the dielectric permittivity and thickness of the dielectric 30 are properly selected. In the example, the two differential signal lines 20a and 20b and the dielectric 30 are adhered with a solder 31 therebetween. In this manner, the portion of the signal line 20 is designed to have the same impedance as the portion of the header 10, so that the whole structure including the header 10 and the signal line 20 can have the desired impedance.

Referring to FIGS. 4A and 4B, S11 is slightly improved as compared with that of the header with no additional signal line. The bandwidth of −3 dB appears at 30 GHz or higher but decreases by 2 dB up to 20 GHz. Therefore, when the ceramic plate, the semiconductor device, and the bonding wire are added, an overall bandwidth may be difficult to satisfy 20 GHz.

Further, S21 is more deteriorated than the bandwidth of only the header with no additional signal lines of FIG. 2B.

In the structure with the inserted dielectric, when the header portion is designed to have the desired impedance, the diameter of the signal line, the distance between the two signal lines, and the dielectric permittivity of the dielectric are determined. Therefore, the space between the signal lines is already determined and fixed based on the designed impedance of the header, and therefore the impedance of the signal line portion is varied depending on a dielectric material inserted in between the signal lines. Although the impedance is improved as the dielectric and the solder are filled in between the signal lines, an effect of improvement was not significant. Further, the bandwidth is more deteriorated than the bandwidth of only the header with no additional signal lines.

Accordingly, there is a need for having advanced techniques and methods for improve RF characteristics while maintaining the structure between the header and the signal line.

### SUMMARY OF THE INVENTION

An embodiment provides a structure for impedance signal lines of a TO-can type semiconductor package.

The objects of the embodiment are not limited thereto and may include objects or effects that may be recognized from a technical solution of a problem or embodiment described herein below although not explicitly mentioned.

According to an embodiment, a transistor outline (TO)-can type semiconductor package includes a header including a semiconductor laser diode disposed on one side thereof; a signal line penetrating the header and including a one end protruding from the one side of the header; and an edge-coupled microstrip (ECM) portion connected to the signal line, the ECM portion including: a dielectric; and ECM lines formed as conductive patterns having predetermined widths and having a predetermined space therebetween on a first side of the dielectric, and respectively connected to the signal lines.

The ECM lines may include two ECM lines formed to be spaced apart from each other at a predetermined space, and the dielectric may have a predetermined thickness.

The ECM portion may further include a ground plane at least partially formed on a second side of the dielectric.

The signal line includes a differential signal line, of which characteristic impedance is varied depending on at least one of the widths of the ECM lines, the space between the ECM lines, the thickness of the dielectric, the kind of the dielectric, and a dielectric permittivity of the dielectric.

The ECM lines may be soldered to the differential signal line.

The ECM lines may be formed to have the same length and the same width.

Total impedance including the ECM lines and the signal line may be determined by adjusting the widths of the ECM lines, the space between the ECM lines, the thickness of the dielectric, the kind of the dielectric, and a dielectric permittivity of the dielectric.

### BRIEF DESCRIPTION OF THE DRAWINGS

FIGS. 1A to 1C are diagrams showing structures for signal lines of a conventional TO-can type module package.

FIGS. 2A and 2B are diagrams showing results of simulating RF characteristics of a conventional signal line structure.

FIGS. 3A and 3B are diagrams showing another structure of a signal line of a conventional TO-can type module package.

FIGS. 4A and 4B are diagrams showing simulation results on RF characteristics of another signal line structure.

FIGS. 5A and 5B are diagrams showing a structure for a signal line of a TO-can type semiconductor package according to an embodiment.

FIGS. 6A to 6D are diagrams showing a structure for an edge-coupled microstrip (ECM) portion shown in FIG. 5.

FIGS. 7A and 7B are first diagrams showing results of simulating RF characteristics of a proposed signal line structure.

FIGS. 8A to 8C are second diagrams showing simulation results on RF characteristics of a proposed signal line structure.

### DETAILED DESCRIPTION OF THE INVENTION

Below, exemplary embodiments of the present disclosure will be described in detail with reference to accompanying drawings.

However, the present disclosure is not limited to the exemplary embodiments set forth herein but may be embodied in various different forms, and one or more elements may be selectively combined and substituted between the exemplary embodiments without departing from the scope of the present disclosure.

Further, the terms (including technical and scientific terms) used in the embodiments of the disclosure may be interpreted as meanings that can be generally understood by a person having ordinary knowledge in the art to which the disclosure pertains, unless otherwise explicitly defined and described, and the terms commonly used, such as tams defined in the dictionary, may be interpreted in consideration of the contextual meaning of the related art.

In addition, the terms used in the embodiments of the disclosure are for the purpose of describing the embodiments only and are not intended to limit the disclosure.

In this specification, the singular forms may include the plural forms as well, unless otherwise mentioned specifically, and description of “at least one (or one or more) among A, B and C” may include one or more of all possible combinations of A, B and C.

Further, in describing the elements in the embodiments of the disclosure, the terms first, second, A, B, (a), (b), etc. may be used.

These terms are only for the purpose of distinguishing the element from other elements, and do not limit the element to the nature, order, sequence, etc. thereof.

When it is described that one element is ‘connected,’ ‘coupled,’ or ‘accessed’ to another element, the elements may be ‘connected,’ coupled,′ or ‘accessed’ not only directly but also by another element provided between them.

Further, when it is described that an element is formed or disposed “on (above) or beneath (below)” another element, the elements may be formed or disposed not only as they are in direct contact with each other but also with one or more other elements therebetween. In addition, the expression “on (above) or beneath (below)” may include not only the meaning of the upper direction but also the meaning of the lower direction with respect to one element.

According to an embodiment, a new structure is proposed in which edge-coupled microstrip (ECM) lines are arranged side by side at one side of two signal lines penetrating a TO-can header, and the ECM line is attached to each signal line.

With recent optical communication technology, a transmission speed is higher than several tens of gigabits per second, and therefore a transistor outline (TO)-can type semiconductor package including a signal line needs to also have a bandwidth of several tens of gigahertz or higher in order to manufacture a transmitter optical sub-assembly (TOSA) and the like optical parts required for the transmission speed. Therefore, the present disclosure proposes a structure that the impedance of the signal line is made as similar as possible to the impedance of the header.

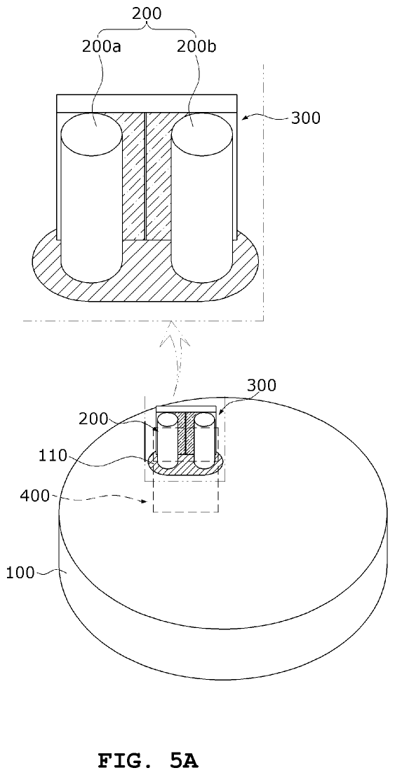

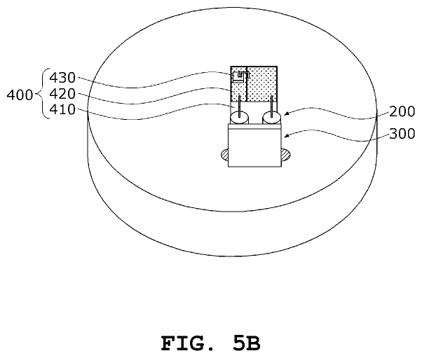

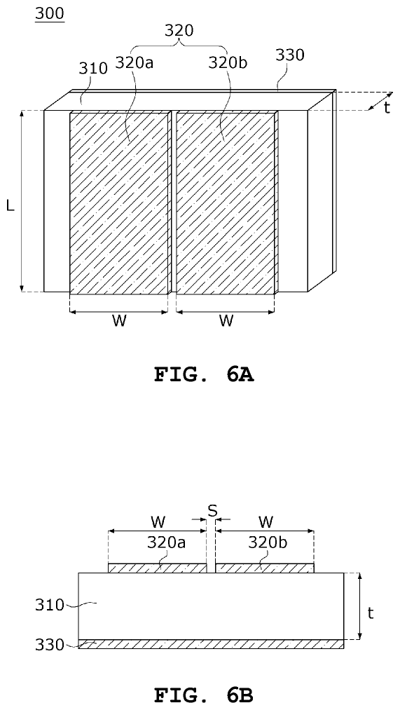

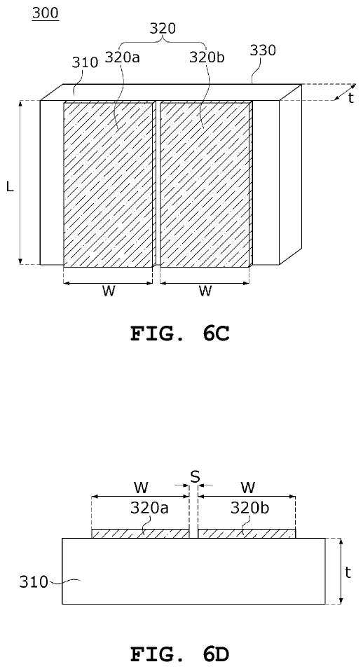

FIGS. 5A and 5B are diagrams showing a structure for a signal line of a TO-can type semiconductor package according to an embodiment, and FIGS. 6A to 6D are diagrams showing a structure for an ECM portion shown in FIG. 5.

Referring to FIGS. 5A and 5B, a TO-can type semiconductor package according to an embodiment of the disclosure may include a header 100, a plurality of signal lines 200, and an ECM portion 300.

The header 100 may include semiconductor parts 400, i.e., a thermoelectric cooler (TEC) 410, a ceramic substrate 420, and a semiconductor laser diode 430, which are arranged in sequence on one side. The header 100 includes a through-hole formed penetrating both sides, and the signal lines 200 are connected via the through hole.

The plurality of signal lines 200 may be connected to the semiconductor laser by a wire bonding method. Here, the wire bonding method is used, but not limited thereto. For example, the plurality of signal lines 200 may include two differential signal lines 200a and 200b, which are not connected to each other to process differential signals.

In this case, the plurality of signal lines 200 passes through the through hole, so that a first end portion can protrude from one side of the header 100, and a second end portion can pass via the through hole and be extended toward the other side of the header 100. The plurality of signal lines 200 may be fastened to the header 100 by a glass material filled in the through hole.

For example, the glass material in powder form may be filled in the through hole, through which the plurality of signal lines 200 passes, and melted at a preset temperature, thereby sealing up the through hole.

The ECM portion 300 may be arranged side by side at one side of the plurality of signal lines 200, and adhere to the signal lines 200. In other words, ECM lines made of a metal and formed in the ECM portion 300 may be respectively connected to the signal lines 200a and 200b. Here, the metal material may be a conductive material, which may for example include copper (Cu), silver (Ag), etc.

The ECM portion 300 may be disposed at an opposite side to the semiconductor part 400 with respect to the signal lines 200.

In this case, the ECM lines, of which impedance has previously been calculated, may be soldered to the signal lines 200 by, for example, a solder ball, but not limited thereto. Alternatively, the ECM lines may adhere to the signal line 200 by laser-based spot welding.

Referring to FIGS. 6A and 6B, the ECM portion 300 according to a first embodiment of the disclosure may include a ceramic substrate or dielectric 310, and an ECM line 320, and the ECM line 320 may include two ECM lines 320a and 320b.

On one side of the dielectric 310, conductive patterns, i.e., two ECM lines 320a and 320b may be formed side by side. The dielectric 310 may be formed to have a predetermined thickness of, for example, 200 μm, but may be changed as necessary. The dielectric 310 may for example be shaped like a hexahedron, but is not limited thereto. Alternatively, the dielectric 319 may have various shapes.

The two ECM lines 320a and 320b are formed to have a preset width W at the center of one side of the dielectric 310, and may have the same width. The two ECM lines 320a and 320b are spaced apart at a predetermined distance S, for example, 10 μm from each other, but the distance S may be changed as necessary.

The two ECM lines 320a and 320b may have the same width W and the same length L. The length L of the two ECM lines 320a and 320b may be shorter than or equal to a protruding length of the signal line. Here, the protruding length may refer to a length by which the signal line protrudes from one side of the header.

Referring to FIGS. 6C and 6D, the ECM portion 300 according to a second embodiment of the disclosure may include the ceramic substrate or dielectric 310, and the ECM line 320, and may further include a metal ground plane 330.

Two ECM lines 320a and 320b may be formed side by side on one side of the dielectric 310, and the ground plane 330 may be formed in at least a portion, i.e., a partial region or the entire region on the other side of the dielectric 310.

The ECM portion 300 according to an embodiment may be used with or without the ground plane added to the other side of the dielectric. The ECM line with or without the ground plane is manufactured and attached to the signal line of the header, so that the signal line of the header is added to a signal line patter portion of the ECM, thereby equivalently forming the ECM having an effect on changing the metal thickness of the ECM line. In this case, the overall characteristic impedance of the ECM line designed to have specific impedance may be slightly different from the initially designed impedance as the signal line of the header is added.

Further, the ECM according to an embodiment is structured to transmit a differential signal, and is more improved in characteristic impedance of the overall structure including the header than the conventional structures, or is configured to adjust the characteristic impedance of the structure including the two signal lines and the ECM into desired impedance by adjusting the width of the ECM or adjusting the space between the ECMs. To be more accurate, in order to optimize an impedance value into a desired impedance value, a structure in which the signal line is added onto the ECM is simulated when the impedance of the ECM line is calculated or simulated.

Here, an ECM transmission line is described as an example, but is not limited thereto. Alternatively, other transmission lines may be taken into consideration. For example, the transmission line may be designed in the form of a differential coplanar waveguide type.

When a hermetic sealing is required like that of the TOSA, it is important to select a material that does not emit gas or the like from the ceramic plate. Further, the parts are made for several tens of gigahertz, and therefore a dielectric material having a low radio frequency loss, i.e., a low loss tangent is selected when the ceramic or other dielectric materials are used. Any type of dielectric may be used as long as the dielectric satisfies such conditions up to the frequency desired to be used. Here, the loss tangent may refer to an index that indicates the loss characteristics of the dielectric.

By connecting the ECM line 320 according to an embodiment to the signal lines 200, overall impedance of the header and the signal line may be improved. In other words, the widths of the ECM lines, the distance between the ECM lines, the thickness of the dielectric, the type of the dielectric, and the dielectric permittivity of the dielectric may be controlled to adjust the characteristic impedance of the signal line so as to be similar to the impedance of the header portion. Therefore, the TO-can type semiconductor package can be improved in RF characteristics.

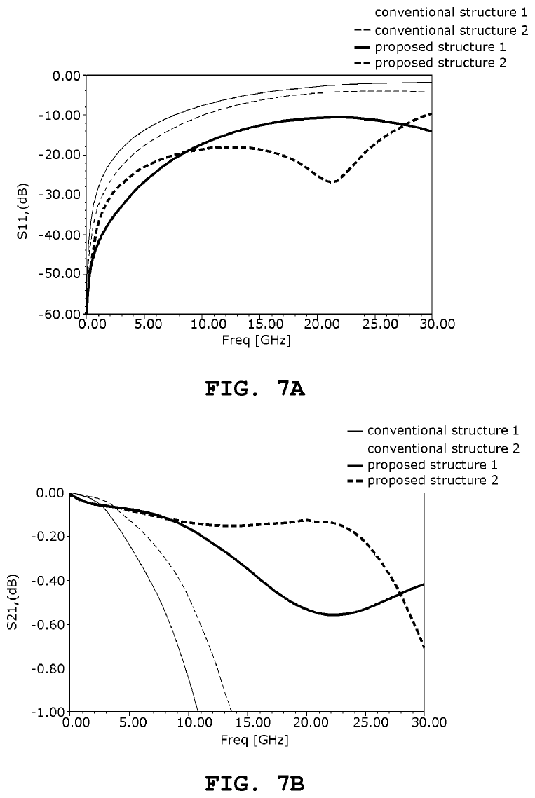

FIGS. 7A and 7B are first diagrams showing results of simulating RF characteristics of a proposed signal line structure.

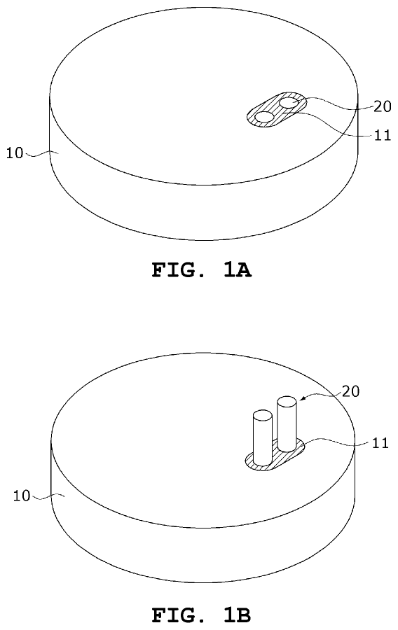

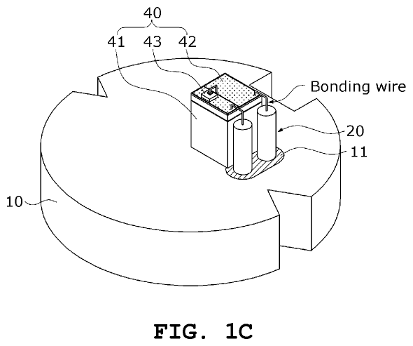

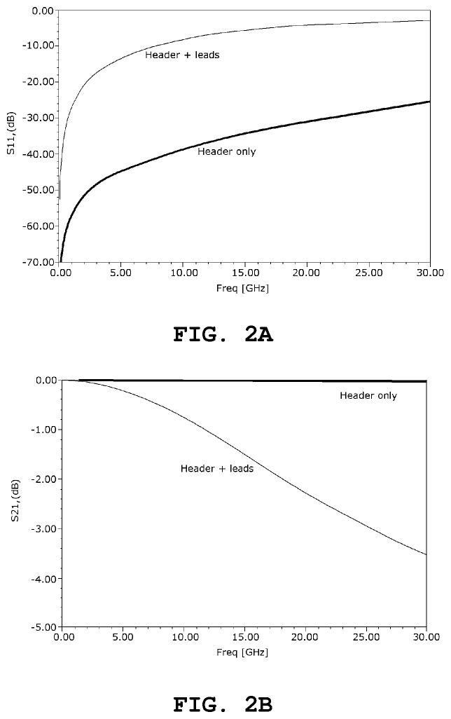

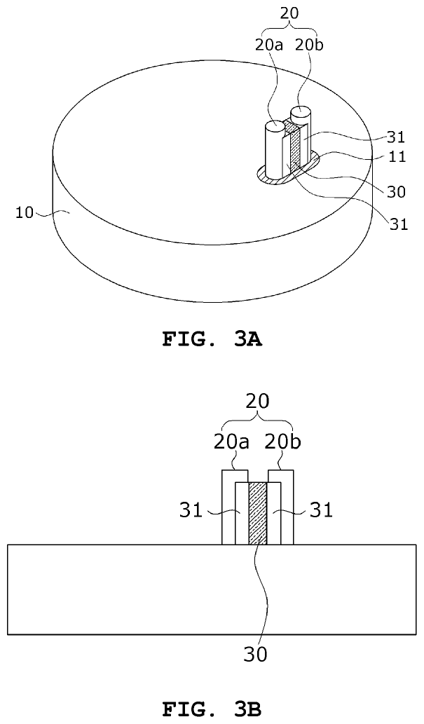

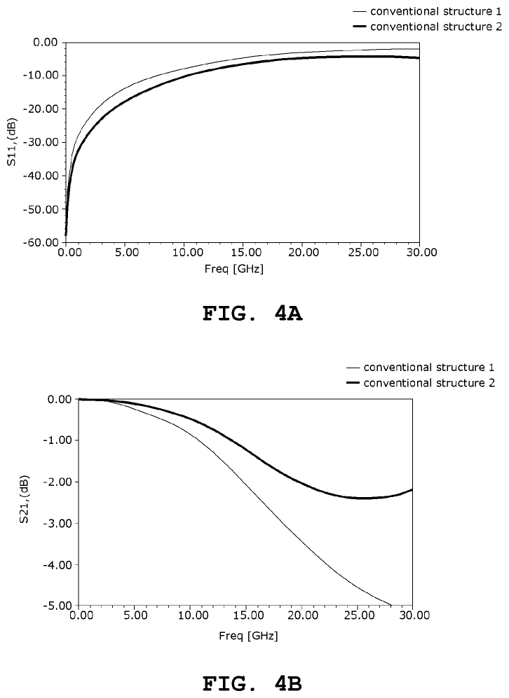

Referring to FIGS. 7A and 7B, in a case of a header having a differential characteristic impedance of 34 [Ohm] by way of example and a differential signal line protruding from above the header, the differential signal line has a differential characteristic impedance considerably different from the characteristic impedance of 34 [Ohm] the header has, as described above. As proposed in the disclosure, the S-parameter of the overall structure including the header and the differential signal line was simulated by adding the ECM to the differential signal line and adjusting the widths of the ECM lines, and compared with the results of simulating the structures shown in FIGS. 1B and 3A. In this case, the signal line protruding from above the header was designed to have a length of 1.1 mm, the ceramic substrate was designed to have a thickness of 200 μm and a dielectric permittivity of 8.8, and the ECM was designed to have a width of 575 μm and have a distance of 10 μm between the ECM lines. Further, the proposed structure 1 includes no ground planes on the back of the ceramic plate, but the proposed structure 2 includes the ground plane.

As compared with the structure of FIG. 1B and the structure of FIG. 3A, it will be appreciated that the proposed structure 1 and the proposed structure 2 are significantly improved in RF characteristics. In the case of the proposed structure 1 and the proposed structure 2, it will be understood that S11 approximately maintains −10 dB or below up to 30 GHz, and S21 has a bandwidth of −1 dB at 30 GHz or higher.

It will be appreciated that S11, S21, and the characteristic impedance are all significantly improved as compared with those of the conventional methods.

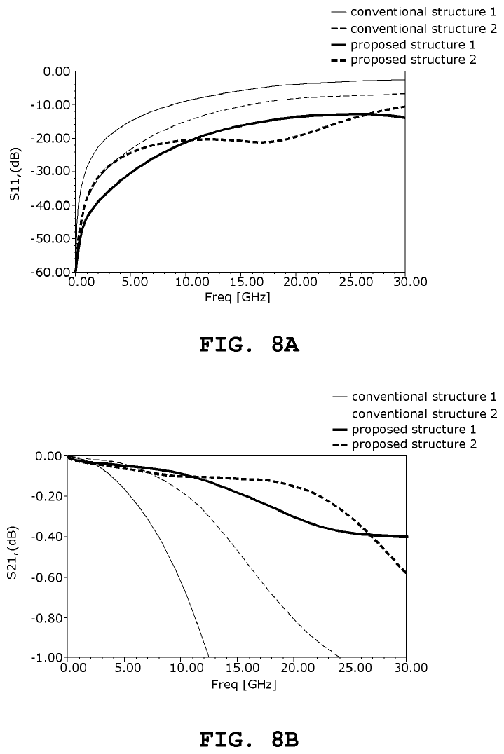

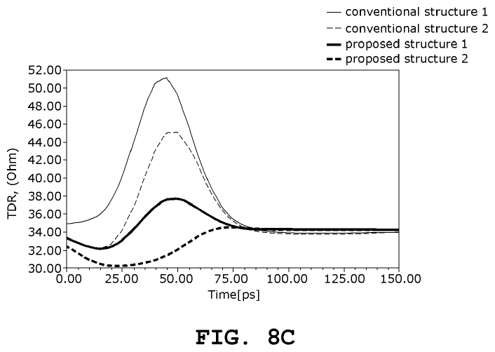

FIGS. 8A to 8C are second diagrams showing results of simulating RF characteristics of a proposed signal line structure

Referring to FIGS. 8A to 8c, in a case of a header having a differential characteristic impedance of 50 [Ohm] by way of another example and a differential signal line protruding from above the header, the differential signal line has a differential characteristic impedance considerably different from the characteristic impedance of 50 [Ohm] the header has. As proposed in the disclosure, the S-parameter of the overall structure including the header and the differential signal line was simulated by adding the ECM to the differential signal line and adjusting the widths of the ECM lines, and compared with the results of simulating the structures shown in FIGS. 1B and 3A. In this case, the signal line protruding from above the header was designed to have a length of 1 mm, the ceramic substrate was designed to have a thickness of 250 μm and a dielectric permittivity of 8.8, and the ECM was designed to have a width of 500 μm and have a distance of 60 μm between the ECM lines. Further, the proposed structure 1 includes no ground planes on the back of the ceramic plate, but the proposed structure 2 includes the ground plane.

As compared with the structure of FIG. 1B and the structure of FIG. 3A, it will be appreciated that the proposed structure 1 and the proposed structure 2 are significantly improved in RF characteristics. In the case of the proposed structure 1 and the proposed structure 2, it will be understood that S11 approximately maintains −10 dB or below up to 30 GHz, and S21 has a bandwidth of −1 dB at 30 GHz or higher. Further, characteristic impedance simulation results based on a time domain reflectometry (TDR) showed that the amount of change was small as compared with the results of a conventional method and other companies.

It will be appreciated that S11, S21, the characteristic impedance, and TDR characteristics are all significantly improved.

According to an embodiment, ECM lines are arranged side by side at one side of two signal lines penetrating a TO-can header, and the ECM lines are respectively attached to the signal lines, thereby significantly improving RF characteristics while maintaining a structure between the header and the signal lines.

According to an embodiment, the characteristic impedance value of the signal line is adjusted by changing the widths of the ECM lines, the distance between the ECM lines, the thickness, kind and dielectric permittivity of the dielectric, etc., thereby reducing difference in impedance between the header and the signal line.

Various merits and effects of the disclosure are not limited to the foregoing description, but will be become apparent while the embodiments of the disclosure are described.

Although a few embodiments of the disclosure have been described, it will be understood by those skilled in the art that various modifications and changes can be made without departing from the spirit and scope of the disclosure defined in the appended claims.

### DESCRIPTION OF REFERENCE NUMERALS

100: header
200: signal line
300: ECM portion
310: dielectric
320: ECM line
330: ground plane

What is claimed is:

1. A transistor outline (TO)-can type semiconductor package comprising:
a header comprising a semiconductor laser diode disposed on one side thereof;
a signal line passing through the header and comprising one end protruding from the one side of the header; and
an edge-coupled microstrip (ECM) portion connected to the signal line,
the ECM portion comprising:
a dielectric; and
ECM lines formed as conductive patterns having predetermined widths and having a predetermined space therebetween on a first side of the dielectric, and respectively connected to the signal lines.

2. The TO-can type semiconductor package according to claim 1, wherein:
the ECM lines comprise two ECM lines formed to be spaced apart from each other at a predetermined distance, and
the dielectric has a predetermined thickness.

3. The TO-can type semiconductor package according to claim 1, wherein the ECM portion further comprises a ground plane at least partially formed on a second side of the dielectric.

4. The TO-can type semiconductor package according to claim 2, wherein the signal line comprises a differential signal line, of which characteristic impedance is varied depending on at least one of: the widths of the ECM lines, the space between the ECM lines, the thickness of the dielectric, the kind of the dielectric, and a dielectric permittivity of the dielectric.

5. The TO-can type semiconductor package according to claim 4, wherein the ECM lines are soldered to the differential signal line.

6. The TO-can type semiconductor package according to claim 1, wherein the ECM lines are formed to have the same length and the same width.

7. The TO-can type semiconductor package according to claim 1, wherein overall impedance including the ECM lines and the signal line is determined by adjusting at least one of: the widths of the ECM lines, the space between the ECM lines, the thickness of the dielectric, the type of the dielectric, and a dielectric permittivity of the dielectric.
